(19) United States
(12) Patent Application Publication
(10) Pub. No.: US 2006/0177071 A1
(43) Pub. Date: Aug. 10, 2006

(54) Method and system for detecting a predetermined sound event such as the sound of breaking glass

(75) Inventor: Kenneth G. Eskildsen, Great Neck, NY (US)

Correspondence Address: Honeywell Law Department,;Patent Services, 101 columbia Road, AB-2, P.O. Box 2245, Morristown, NJ, 07962-2245, US

(73) Assignee: HONEYWELL INTERNATIONAL, INC., MORRISTOWN, NJ (US)

(21) Appl. No.: 11/052,674

(22) Filed: Feb. 7, 2005

(51) Int. Cl. H04R 29/00; H03G 3/00

(52) U.S. Cl. 381/56; 381/58; 381/61

(57) ABSTRACT

A method and system for detecting a predetermined sound event, such as the sound of breaking glass. Data representing monitored sounds is stored, such as in a circular buffer, while a preliminary assessment is made in real time as to whether the monitored sounds potentially include the predetermined sound event. If there is a potential correspondence, the already stored, pre-event data is frozen, and additional data including, and following, the event is stored. Next, the stored pre-event and additional data is retrieved from storage and provided to a processor that applies one or more algorithms to determine, with finality, if the event corresponds to the predetermined sound event.

### BACKGROUND OF THE INVENTION

1. Field of Invention

The invention relates generally to a method and system for detecting a predetermined sound event such as the sound of breaking glass.

2. Description of Related Art

Sound processors are used to detect predetermined sounds. For example, glass breakage sensors are designed to detect the breakage of framed glass within the perimeter of a protected space. One or more of such sensors may be arranged in the protected space along with other sensors such as motion detectors, and window or door switches that detect the opening of a window or door, respectively. When any of the sensors detects an intrusion, the sensor transmits a signal to a control panel that then sounds an alarm. Glass breakage sensors commonly include a microphone and an audio processor to monitor the sounds within the protected space to determine if the glass has been broken. Typically, this is achieved by determining if the level of the monitored sound exceeds a threshold. A problem with this arrangement is that sounds other than that of breaking glass, such as a dog barking, a balloon pop, or the closing of a kitchen cabinet, can fool existing audio processors and cause false alarms. As such, it is desirable to build a device that will detect the breaking of a window, or other predetermined sound events, while reducing or eliminating false alarms cause by similar sounds.

### BRIEF SUMMARY OF THE INVENTION

The present invention addresses the above and other issues by providing a method and system for detecting a predetermined sound event. In one possible implementation, the method and system is used for detecting the sound of breaking glass, where data representing monitored sounds in a protected spaced is stored while a preliminary assessment is made in real time as to whether the monitored sounds may include a glass breakage event. If the preliminary assessment indicates there is a glass breakage event, additional data is stored. Next, the stored data representing the monitored sounds before, during and after the event is retrieved from storage and provided to a processor, which applies any number of more detailed algorithms to determine, with finality, if the event should be declared an actual glass break event.

The invention may be adapted for use in detecting other sound events, e.g., thunder, lightning, voices, gun shots, and the like.

In particular, in one aspect of the invention, a sound processor for detecting a predetermined sound event includes a microphone for monitoring sounds, a storage resource for storing first data representing the monitored sounds over a first time period, first circuitry for determining if the monitored sounds potentially include the predetermined sound event, and second circuitry responsive to the first circuitry for storing second data representing the monitored sounds over a second time period that follows the first time period when the first circuitry determines that the monitored sounds potentially include the predetermined sound event.

In a further aspect of the invention, a sound processor for detecting a predetermined sound event includes means (110) for monitoring sounds, means (136) for storing first data representing the monitored sounds over a first time period, first means (130) for determining if the monitored sounds potentially include the predetermined sound event, and second means (137) responsive to the first means for storing second data representing the monitored sounds over a second time period that follows the first time period when the first means determines that the monitored sounds potentially include the predetermined sound event.

In a further aspect of the invention, a method for detecting a predetermined sound event includes monitoring sounds (110), storing first data (136) representing the monitored sounds over a first time period, determining (130) if the monitored sounds potentially include the predetermined sound event, and storing second data (137) representing the monitored sounds over a second time period that follows the first time period when the determining step determines that the monitored sounds potentially include the predetermined sound event.

### BRIEF DESCRIPTION OF THE DRAWINGS

In the drawings:

In all the Figures, corresponding parts are referenced by the same reference numerals.

FIG. 1 illustrates a block diagram of a sound processor apparatus, according to the invention; and

FIG. 2 illustrates a block diagram of an application-specific integrated circuit (ASIC) for use in a sound processor, according to the invention.

### DETAILED DESCRIPTION OF THE INVENTION

Generally, the invention improves the reliability of sound processors used for detecting predetermined sounds. In an example implementation, the invention improves the acoustic glass breakage detector false alarm problem by using an improved sensor architecture that allows for the use of a more sophisticated, reliable detection algorithm. Furthermore, the invention allows for the use of multiple audio processor algorithms to detect the breakage of framed glass, thereby increasing the reliability of the detection even further. The improved architecture allows for processing of pre-detection and post-detection audio to distinguish between actual and nuisance alarms. The architecture is suitable for hardwired, Honeywell V-plex™ polling loop technology, and wireless applications, for instance. Moreover, the invention can be implemented using a conventional microprocessor as well as a digital signal processor (DSP). In addition, the detector is software upgradeable without the need for hardware changes to accommodate new detection algorithms that may be developed.

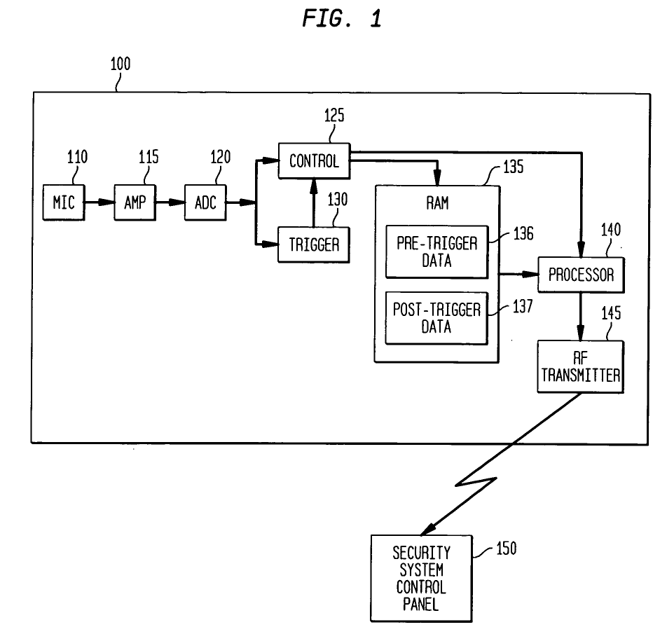

FIG. 1 illustrates a block diagram of a sound processor, according to the invention. The apparatus, shown generally at 100, includes a microphone (MIC) for monitoring sounds. In a security system application, the sounds may be monitored in a protected space, such as a room. The microphone 110 outputs an analog audio signal that is amplified by an amplifier (AMP) 115. The output from the amplifier 115 is digitized at an analog-to-digital converter (ADC) 120 to provide digitized audio samples to a control circuitry 125 and a trigger circuitry 130.

The control circuitry 125 stores the digitized audio samples in a subset area 136 of a storage resource such as a random access memory (RAM) 135 dedicated to pre-event (pre-trigger) audio samples. The control circuitry 125 ensures that the ADC samples remain within the bounds of the pre-trigger RAM and keeps track of the oldest and newest samples. The samples may be stored in a first-in, last-out manner so that the subset storage area 136 provides a circular buffer in which samples that represent the monitored sounds for a first predetermined time period preceding an event that potentially corresponds to a predetermined sound event are stored. As each new sample is stored, the oldest sample is overwritten. The digitizing and storage of samples in the subset storage area 136 continues during pre-event operation, prior to when the event is detected. In particular, the trigger circuitry 130 determines if the monitored sounds potentially include a predetermined sound event. For example, this may be achieved by determining, substantially in real-time, whether the audio samples exceed a predetermined threshold. When the audio samples exceed the predetermined threshold, the trigger circuitry 130 signals the control circuitry 125 to store subsequent samples in a second subset storage area 137, termed a post-trigger area, of the memory 135. In particular, samples that represent the monitored sounds over a second time period that follows the first time period are stored in the subset storage area 137. For example, samples that represent the monitored sounds during, and following, the potential glass break event over the second time period may be stored in the subset storage area 137. Once the pre-trigger and post-trigger RAM subset areas 136 and 137, respectively, have been filled, there is essentially a recording of the audio data before, during and after the potential trigger event. At this point, the control circuitry 125 signals the processor 140 to retrieve the pre-event and post-event samples from the subset storage areas 136 and 137, and to process the samples, which represent a recorded audio signal. Note that the use of separate designated storage areas in the RAM 135 for pre-event and post-event data is one possible implementation, as other arrangements are possible. The post-event or post-trigger data may include the data from during the potential trigger event as well.

The processor 140 can perform one or a multitude of algorithms on the recorded signal without concern that information will be lost due to processing latency. In addition, the algorithms can process the audio that occurred before and/or after the trigger event to help determine, with finality, whether the monitored sounds include the predetermined sound event. For example, the processor 140 may determine whether a potential glass break event should be declared an actual glass break event. This approach is compatible with existing algorithms, such as those used in the Honeywell FlexGuard® FG series of detectors, for instance. Examples of known glass break detection algorithms are described in U.S. Pat. No. 6,236,313 to Eskildsen et al., issued May 22, 2001, and entitled “Glass Breakage Detector”, U.S. Pat. No. 6,351,214 to Eskildsen et al., issued Feb. 26, 2002, and entitled “Glass Breakage Detector”, and U.S. Pat. No. 6,538,570 to Smith, issued Mar. 25, 2003, and entitled “Glass-Break Detector and Method of Alarm Discrimination”, each of which is incorporated herein by reference.

The approach described herein provides advantages over other systems that only process audio data in real time. This limits such systems to algorithms that can be performed between audio samples, where a predetermined change between samples triggers an event, or by comparing audio samples to a predetermined threshold, where an event is triggered if a sample exceeds the predetermined threshold. These approaches also limit the bandwidth of the signals that could be processed because higher bandwidth signals shorten the time between audio samples and thereby shorten the amount of processing that can be performed between samples because the processing occurred in real-time. In contrast, with the present invention, more detailed and reliable algorithms can be used. When multiple algorithms are used, the results from each can be factored in deciding whether there is an actual glass break event. Moreover, a priority or weight may be assigned to the algorithms so that those that are known to be more reliable are given more weight in deciding whether the monitored sounds include the predetermined sound event. Furthermore, a statistical approach may be used where one or more algorithms provide a probability that the monitored sounds include the predetermined sound event, and a final determination is made by accounting for the probabilities from each algorithm. The invention can employ only one algorithm as well.

If the processor 140 determines that the monitored sounds include the predetermined sound event, such as a glass break event, it may activate a transmitter 145, such as a wireless RF transmitter, to transmit an alarm signal to a security system control panel 150. It may also send the alarm signal to the control panel via a wired connection.

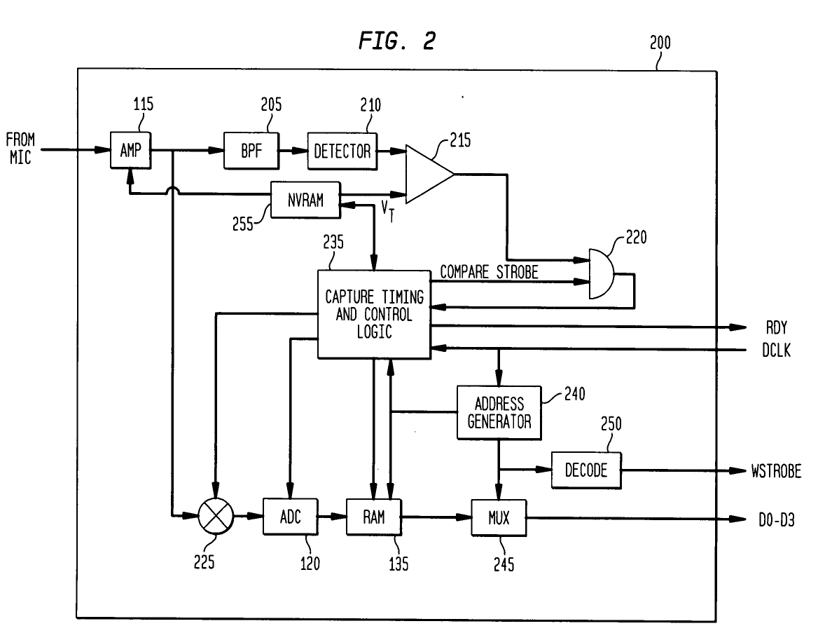

FIG. 2 illustrates a block diagram of an application-specific integrated circuit (ASIC) for use in a sound processor, according to the invention. In one possible approach, the AMP 115, ADC 120, control circuitry 125, trigger circuitry 130 and RAM 135 of FIG. 1 are provided in an ASIC 200. The ASIC described herein is a custom integrated circuit used for the signal conditioning of a microphone-generated signal and for buffering that signal for application to an external micro-controller or DSP integrated circuit, such as the processor 140.

At the center of the ASIC 200 is a capture timing and control function 235, e.g., a control, which receives a voltage controlled oscillator (VCO) clock signal and generates a series of sequential pulses that are used to sample data, at a sample and hold (S/H) circuit 225, convert data at an ADC 120, provide a compare strobe to an AND gate 220, and store data in the memory 135. These pulses all occur at the same repetition rate and are time shifted from one another, based on S/H, A/D, CODEC and memory timing requirements. Also, an internal countdown clock generates a clock signal suitable for running a microcontroller, such as the processor 140. The mode as to Read or Write is determined by a R/W-PROG input. The capture timing and control function 235 provides a RDY (ready) signal to the processor 140 to inform the processor that data is ready to be output from the memory 135 for analysis to determine whether an actual glass break event has occurred. The processor responds to the RDY signal by providing a data clock signal DCLK, which causes the data in the memory 135 to be output to the processor.

In further detail, the microphone's signal is pre-amplified, passed through an equalization filter, and low pass filtered at the AMP 115. The equalizer corrects for the diminished high-end frequency response from the microphone. The low pass filter, which can be part of the equalizer, is used to band limit the input signal so as to prevent aliasing when digitizing the analog signal. The functions of the AMP 115 may be combined as a single, signal conditioning circuitry block.

The output of the AMP 115 is sent through a bandpass filter (BPF) 205 and then a detection circuit 210, which converts the AC audio signal into a slowly varying DC level. The value of this detected signal is compared to a reference threshold voltage (V_{T}), at a comparator 215, and, if it exceeds the threshold, it is fed as a logic level to a strobed AND gate 220. That is, as mentioned, the capture timing and control logic function 235. provides a compare strobe to the AND gate 220. If the detected signal is large enough, the capture timing and control logic function 235 is responsive to the strobed output of the AND gate 220 for starting a preset timer to fill up a memory bank in the RAM 135 with post-event data.

The output of the AMP 115 is also sent to the sample and hold circuit 225 and the ADC 120, which periodically sample the audio signal and convert it into a twelve bit digital representation. The data is continuously stored in a 1K×12 circular buffer in the RAM 135 and, after 1,024 samples, the data is over-written. As mentioned, this buffer acts as a pre-event storage. In one possible configuration, the RAM 135 may be an 8K×12-bit memory array partitioned as a dual bank memory. When a potential glass break event is detected, based on the output of the AND gate 220, the capture timing and control logic function 235 freezes the circular buffer in the RAM 135 and directs an additional 7K×12 memory bank in the RAM 135 to be filled up with post-event data as it is received. The allocation of the RAM 135 between pre-event and post-event data can be set as desired or as needed by the detection algorithms used. Once the additional 7K of data is stored, all data in the memory is frozen and retained until it is externally clocked out to the processor 140 on the four output data lines D0-D3, responsive to the DCLK signal. When the memory 135 is fully loaded, the RDY (ready) level flag signal is raised by the capture timing and control logic function 235, indicating to an external controller, such as the processor 140, that the data is ready to be retrieved and processed. In particular, The RDY line is used to annunciate when a potential glass break event has occurred and, in addition, when a complete data record has been fully stored in the internal memory 135. A single sampling clock period pulse on the RDY line provides the annunciation. A data record fully stored indication is that the RDY line goes to a HI. It is restored to logic LO upon the first negative-going edge of the DCLK signal.

Internal address counting circuitry in the function 235 arranges the data from the 1K circular buffer and the 7K memory to appear as sequential, contiguous, stored, sampled data. In particular, the capture timing and control logic function 235 sends clock signals to the RAM 135 that cause the stored data to be output to the processor 140 over four parallel data lines (D0 to D3) as groups of three 4-bit nibbles. A total of 8,192×3 clock pulses completely read out all of the data. The most significant bit (MSB) of the first nibble of the three-nibble data word is identified by a WSTROBE signal going high. In particular, although there are twelve-bit data words stored in the memory, there are only four data output lines, in the example implementation. The multiplexer (MUX) 245 follows the RAM 135 and selects from the 12-bit parallel output word, one of three 4-bit data nibbles. As successive DCLK pulses come in, the MUX 245 sequences through the three, 4-bit nibbles. Two address lines control the nibble selection, where only three out of four possible address combinations are used. At a decode function 250, the MSB of the nibble is decoded and is used to form the WSTROBE signal.

The DCLK input advances an address pointer provided by an address generator 240 that controls the memory 135. DCLK is also used as a clock that loads data into a non-volatile memory 255 when in a Program Mode during ASIC final test. The appearance of the DCLK signal also is used to reset the RDY signal flag. DCLK is additionally used during system test to clock data into the NVRAM Registers and into the NVRAM.

The address generator 240 is responsive to the DCLK signal for generating a pointer address for the memory 135, both for storing and retrieving data. The address generator 240 can be set up so that, after a RDY signal is generated, and all data in the memory 135 is frozen, sending in 8,192×3 clock signals on the DCLK line will result in data retrieval of the entire record. Data will be output in parallel across the four data lines. The 1,024 bytes stored in the 1K, pre-event segment of memory may be output first, with data from the furthest back first and the most recent data last, e.g., on a first-in, first-out basis. The next byte output would be from the post-event, 7K-memory bank segment, starting with the byte stored at the time slot just after when the compare strobe was generated. In one possible approach, the output of the memory 135 is a time sequence unequally bracketing the time when the compare strobe was generated, with one-eighth of the data being prior and seven-eighths of the data being after the compare strobe was generated, yielding a 12.5% pre-trigger of look-ahead data, in one possible approach.

The ASIC 200 may further contain an internal voltage regulator to provide on-chip operating voltage and any necessary reference voltages. An internal sixteen-bit nonvolatile (NVRAM) 255 inside the ASIC 200 may be used for presetting the threshold voltage (V_{T}), the attenuator value of the microphone signal in the AMP 115, and for viewing internal test points. An internal voltage controlled oscillator (VCO) is referenced to an external crystal and used for digital filter clock generation, memory clock generation and also for outputting an external clock that can be used by the processor. The detailed timing and control are performed in the capture timing and control logic function 235. The NVRAM 255 is loaded by shifting 4-bit wide parallel data words, over the four data lines, into four, 4-bit registers, and clocked in using the DCLK line.

Additionally, power saving logic may be used in the ASIC 200 to save battery power by cycling off circuitry that has no requirement for being on during certain phases of operation. An example of this is 7K post-event storage area of the 8K-memory array 135, which is only used after a potential glass break event has occurred.

While there has been shown and described what are considered to be preferred embodiments of the invention, it will, of course, be understood that various modifications and changes in form or detail could readily be made without departing from the spirit of the invention. It is therefore intended that the invention not be limited to the exact forms described and illustrated, but should be construed to cover all modifications that may fall within the scope of the appended claims.

What is claimed is:

1. A sound processor for detecting a predetermined sound event, comprising:
a microphone for monitoring sounds;
a storage resource for storing first data representing the monitored sounds over a first time period;
first circuitry for determining if the monitored sounds potentially include the predetermined sound event; and
second circuitry responsive to the first circuitry for storing second data representing the monitored sounds over a second time period that follows the first time period when the first circuitry determines that the monitored sounds potentially include the predetermined sound event.

2. The sound processor of claim 1, wherein:
the predetermined sound event comprises a glass break event.

3. The sound processor of claim 1, wherein:
the second circuitry freezes the first data stored in the storage resource when the first circuitry determines that the monitored sounds potentially include the predetermined sound event.

4. The sound processor of claim 1, wherein:
the first data represents the monitored sounds preceding the monitored sounds that potentially include the predetermined sound event; and
the second data represents the monitored sounds including, and following, the monitored sounds that potentially include the predetermined sound event.

5. The sound processor of claim 1, further comprising:
third circuitry for processing the first data and the second data to determine, with finality, whether the monitored sounds include the predetermined sound event.

6. The sound processor of claim 5, wherein:
the third circuitry applies a plurality of sound detection algorithms to the first data and the second data to determine, with finality, whether the monitored sounds include the predetermined sound event.

7. The sound processor of claim 1, wherein:
the first data and the second data are stored in separate designated storage locations.

8. The sound processor of claim 1, wherein:
the first circuitry determines if the monitored sounds potentially include the predetermined sound event by comparing a level of the monitored sounds to a predetermined threshold as the monitored sounds are received.

9. The sound processor of claim 1, wherein:
the storage resource comprises a circular buffer.

10. A sound processor for detecting a predetermined sound event, comprising:
means for monitoring sounds;
means for storing first data representing the monitored sounds over a first time period;
first means for determining if the monitored sounds potentially include the predetermined sound event; and
second means responsive to the first means for storing second data representing the monitored sounds over a second time period that follows the first time period when the first means determines that the monitored sounds potentially include the predetermined sound event.

11. The sound processor of claim 10, wherein:
the predetermined sound event comprises a glass break event.

12. The sound processor of claim 10, wherein:
the second means freezes the first data stored in the storing means when the first means determines that the monitored sounds potentially include the predetermined sound event.

13. The sound processor of claim 10, wherein:
the first data represents the monitored sounds preceding the monitored sounds that potentially include the predetermined sound event; and
the second data represents the monitored sounds including, and following, the monitored sounds that potentially include the predetermined sound event.

14. The sound processor of claim 10, further comprising:
third means for processing the first data and the second data to determine, with finality, whether the monitored sounds include the predetermined sound event.

15. The sound processor of claim 14, wherein:
the third means applies a plurality of sound detection algorithms to the first data and the second data to determine, with finality, whether the monitored sounds include the predetermined sound event.

16. A method for detecting a predetermined sound event, comprising:
monitoring sounds;
storing first data representing the monitored sounds over a first time period;
determining if the monitored sounds potentially include the predetermined sound event; and
storing second data representing the monitored sounds over a second time period that follows the first time period when the determining step determines that the monitored sounds potentially include the predetermined sound event.

17. The method of claim 16, further comprising:
freezing the first stored data when the determining step determines that the monitored sounds potentially include the predetermined sound event.

18. The method of claim 16, wherein:
the first data represents the monitored sounds preceding the monitored sounds that potentially include the predetermined sound event; and
the second data represents the monitored sounds including, and following, the monitored sounds that potentially include the predetermined sound event.

19. The method of claim 16, further comprising:
processing the first data and the second data to determine, with finality, whether the monitored sounds include the predetermined sound event.

20. The method of claim 19, wherein:
the processing applies a plurality of sound detection algorithms to the first data and the second data to determine, with finality, whether the monitored sounds include the predetermined sound event.
